(19) United States
(12) Patent Application Publication
(10) Pub. No.: US 2008/0292991 A1
(43) Pub. Date: Nov. 27, 2008

(54) HIGH FIDELITY MULTIPLE RESIST PATTERNING

(75) Inventors: Thomas I. Wallow, San Carlos, CA (US); Ryoung-Han Kim, San Jose, CA (US); Jongwook Kye, Pleasanton, CA (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/753,443

(22) Filed: May 24, 2007

(51) Int. Cl. G03C 5/00; H01L 21/31

(52) U.S. Cl. 430/312; 438/761; 257/E21.002

(57) ABSTRACT

An integrated circuit fabrication process as described herein employs a double photoresist exposure technique. After creation of a first pattern of photoresist features on a wafer, a second photoresist layer is formed over the first pattern of photoresist features. The second photoresist layer is subjected to a reflow step that softens and relaxes the second photoresist material. This reflow step causes the exposed surface of the second photoresist layer to become substantially planar. Thereafter, the second photoresist layer can be exposed and developed to create a second pattern of photoresist features on the wafer. The planar surface of the second photoresist layer, which results from the reflow step, facilitates the creation of accurate, precise, and “high fidelity” photoresist features from the second photoresist material.

### TECHNICAL FIELD

Embodiments of the disclosed subject matter relate generally to integrated circuit (IC) fabrication. More particularly, the embodiments relate to a technique for improving the quality of photoresist patterns associated with multiple-patterning IC wafer fabrication processes.

### BACKGROUND

The semiconductor or IC industry aims to manufacture ICs with higher and higher densities of devices on a smaller chip area to achieve greater functionality and to reduce manufacturing costs. This desire for large scale integration has led to a continued shrinking of circuit dimensions and device features. The ability to reduce the size of structures, such as gate lengths in field-effect transistors and the width of conductive lines, is driven by lithographic performance.

With conventional lithography systems, radiation is provided through or reflected off a mask or reticle to form an image on a semiconductor wafer. Generally, the image is focused on the wafer to expose and pattern a layer of material, such as photoresist material. In turn, the photoresist material is utilized to define doping regions, deposition regions, etching regions, or other structures associated with ICs in one or more layers of the semiconductor wafer. The photoresist material can also define conductive lines or conductive pads associated with metal layers of an IC. Further, the photoresist material can define isolation regions, transistor gates, or other transistor structures and elements.

A multiple exposure process, which utilizes two or more lithography sub-processes, can be used to form photoresist patterns of extremely small and tightly packed features. One type of double exposure process forms a first photoresist pattern, etches the wafer using the first photoresist pattern, subsequently forms a second photoresist pattern, and etches the wafer using the second photoresist pattern. Another type of double exposure process forms a first photoresist pattern, coats the first photoresist pattern with a second photoresist layer, exposes and develops the second photoresist layer, and then etches the wafer. This double exposure process is sometimes referred to as a double exposure single etch process.

In conventional double exposure single etch processes, the first photoresist pattern may cause the formation of surface irregularities and surface contours in the second photoresist layer, which is coated over the first photoresist pattern. As a simple example, the left side of FIG. 1 depicts features 12 in a first photoresist pattern that has been coated with a second photoresist layer 14. The exaggerated lumps in second photoresist layer 14 represent the irregularities and contours caused by features 12. Such surface irregularities and surface contours are amplified when the features in the first photoresist pattern have a relatively high aspect ratio (i.e., the height-to-width ratio)—the exposed surface of the second photoresist layer tends to follow the general contour of the first photoresist pattern. Therefore, the resulting exposed surface of the second photoresist layer will be non-planar. This non-planar characteristic creates lensing and/or other optical effects that can adversely impact the manner in which light exposes the second photoresist layer during pattern exposure. For example, the exposing light can be refracted or reflected in unpredictable ways that might alter the intended pattern, or the limited focal length of the lithographic tool may not be able to adequately focus on the varying height of the non-planar surface. Consequently, the developed features in the second photoresist layer may be distorted, irregular, or otherwise “imperfect” for the intended etching step. In this regard, the right side of FIG. 1 depicts the wafer after exposure and development of second photoresist layer 14. A distorted feature 16 in the second photoresist pattern has resulted from the non-planar surface of second photoresist layer 14.

Ultimately, distorted features in the second photoresist pattern may result in undesirable features in the subsequently etched layers. Inaccuracies in the etched layers may in turn result in a scrapped wafer or scrapped devices.

### BRIEF SUMMARY

The techniques and technologies described herein can be utilized to create “high fidelity” photoresist features in a double exposure single etch process. The second photoresist layer is subjected to a reflow process step during which the second photoresist material is softened in a manner that relaxes its exposed surface. The reflow step results in a planarized exposed surface, which exhibits desirable optical characteristics. The planarized second photoresist layer is then exposed using patterned radiation, and developed to form accurate photoresist features from the second photoresist material. The overall photoresist pattern of the wafer includes photoresist features from the first pattern combined with photoresist features from the second pattern.

One embodiment may be carried out by a method of creating accurate photoresist features on a semiconductor wafer. The method involves: creating a first pattern of photoresist features over a target material of the semiconductor wafer; forming a second photoresist layer over the target material and over the first pattern of photoresist features, the second photoresist layer having a non-planar exposed surface that is influenced by the first pattern of photoresist features; and reflowing the second photoresist layer to relax the non-planar exposed surface, resulting in a substantially planarized (hereinafter referred to as “planarized” or “planar”) exposed surface of the second photoresist layer.

Another embodiment is carried out by a method of processing a semiconductor wafer. The method involves: creating, from a first photoresist material, a first pattern of photoresist features over a target material of the semiconductor wafer; applying a second photoresist material over the target material and over the first pattern of photoresist features; heating, for a period of time, the second photoresist material at a bake temperature to soften the second photoresist material while preserving the first pattern of photoresist material, resulting in a planarized exposed surface of the second photoresist material; exposing the second photoresist material with patterned radiation, resulting in an exposed second photoresist layer; and developing the exposed second photoresist layer into a second pattern of photoresist features, where the first pattern of photoresist features and the second pattern of photoresist features form an overall photoresist pattern for the semiconductor wafer.

Another embodiment is carried out by a method of processing a semiconductor wafer. The method involves: creating, from a first photoresist material, a first pattern of photoresist features over a target material of the semiconductor wafer; applying a second photoresist material over the target material and over the first pattern of photoresist features; exposing, for a period of time, the second photoresist material to a solvent to soften the second photoresist material while preserving the first pattern of photoresist material, resulting in a planarized exposed surface of the second photoresist material; exposing the second photoresist material with patterned radiation, resulting in an exposed second photoresist layer; and developing the exposed second photoresist layer into a second pattern of photoresist features, where the first pattern of photoresist features and the second pattern of photoresist features form an overall photoresist pattern for the semiconductor wafer.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a diagram that depicts a cross section of a wafer undergoing a prior art double exposure single etch process;

FIG. 2 is a schematic representation of a lithographic system suitable for use in patterning a wafer; and

FIGS. 3-12 are cross sectional views illustrating a wafer undergoing a double exposure single etch process.

### DETAILED DESCRIPTION

The following detailed description is merely illustrative in nature and is not intended to limit the embodiments of the invention or the application and uses of such embodiments. For the sake of brevity, conventional techniques and technologies related to photolithography, photoresist material composition, and semiconductor device fabrication may not be described in detail herein.

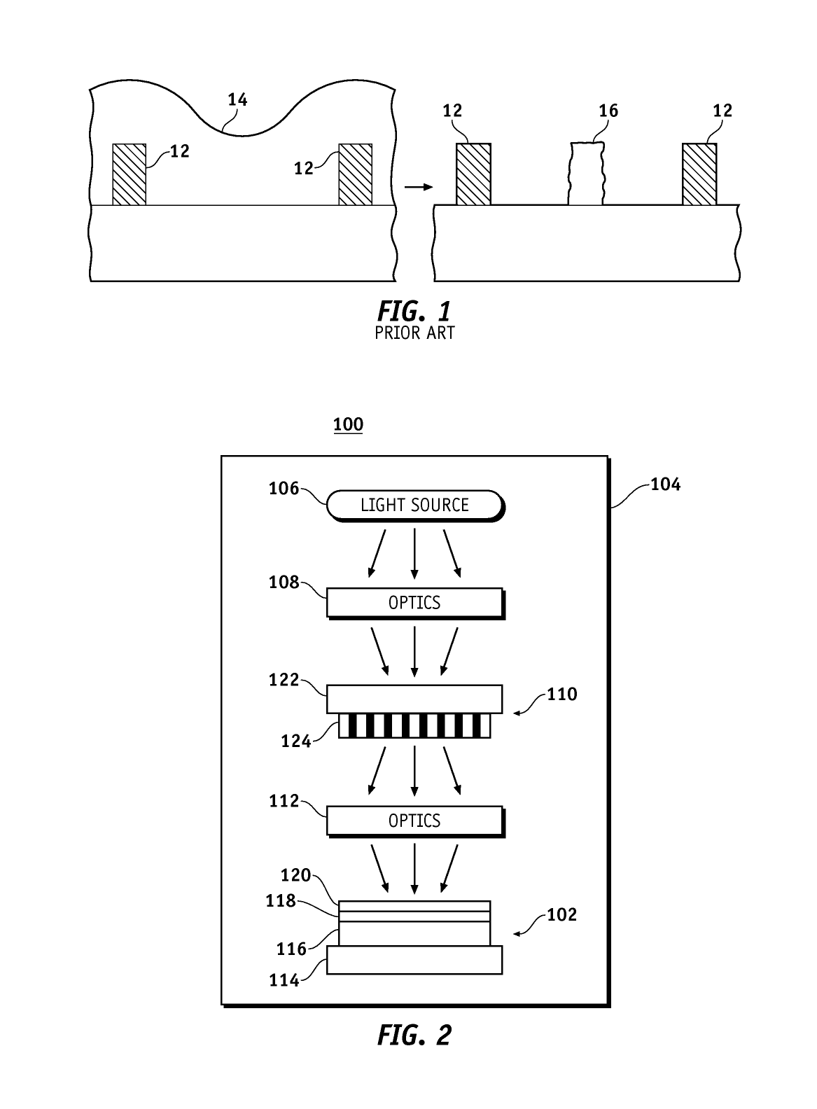

FIG. 2 is a schematic representation of a lithographic system 100 for patterning a wafer 102. Lithographic system 100 includes a chamber 104, a radiation source 106, a condenser lens assembly 108 (labeled “Optics” in FIG. 1), a mask or a reticle 110, an objective lens assembly 112 (labeled “Optics” in FIG. 1), and a stage 114. Lithographic system 100 is configured to transfer a pattern or image provided on mask or reticle 110 to a target material or surface of wafer 102. Lithographic system 100 may be a lithographic camera or stepper unit. For example, lithographic system 100 may be an XT1400 series machine manufactured by ASML or an S308F system from Nikon.

Wafer 102 includes a substrate 116, a layer 118, and a photoresist layer 120. Photoresist layer 120 is disposed over layer 118, and layer 118 is disposed over substrate 116. Wafer 102 depicted in FIG. 1 can be an entire IC wafer or a portion of an IC wafer. Wafer 102 can be a portion of an IC, such as a memory, a processing unit, an input/output device, or the like, or multiple ICs. Substrate 116 can be a semiconductor substrate, such as silicon, gallium arsenide, germanium, or any suitable substrate material. Substrate 116 can include one or more layers of material and/or features, such as lines, interconnects, vias, doped regions, or the like, and substrate 116 can further include devices or portions thereof, such as transistors, microactuators, microsensors, capacitors, resistors, diodes, or the like.

Layer 118 can be an insulative layer, a conductive layer, a barrier layer, or any target material to be etched, doped, treated, processed, or layered. In one embodiment, layer 118 includes one or more layers of materials, such as polycrystalline silicon and/or one or more of titanium silicide, tungsten silicide, cobalt silicide, and/or other materials alone or in alternating layers. In another embodiment, layer 118 is a hard mask layer, such as a silicon nitride layer or a metal layer. The hard mask layer can serve as a patterned layer for processing substrate 116 or for processing a layer upon substrate 116. In yet another embodiment, layer 118 is an anti-reflective coating (ARC). Substrate 116 and layer 118 are not described in a limiting fashion, and can each comprise a conductive, semiconductive, or insulative material.

Photoresist layer 120 can comprise a variety of photoresist materials, compositions, or chemicals suitable for lithographic applications. Photoresist layer 120 is selected to have photochemical reactions in response to electromagnetic radiation emitted from radiation source 106 and to have sufficient transparency to the electromagnetic radiation to allow useful patterning of the photoresist layer. Materials comprising photoresist layer 120 can include, among others, a matrix material or resin, a sensitizer or inhibitor, and a solvent. Photoresist layer 120 may be a chemically amplified, positive or negative tone, organic-based photoresist. Photoresist layer 120 may also be a silicon-containing photoresist. Photoresist layer 120 may be, but is not limited to, an acrylate-based polymer, an alicyclic-based polymer, or a phenolic-based polymer.

Photoresist layer 120 is formed over the target material or layer of wafer 102 using any suitable technique, for example, deposition by spin coating over layer 118. The thickness of photoresist layer 120 is selected according to the particular lithographic technology, e.g., for use in vacuum ultraviolet (VUV) lithography, deep ultraviolet (DUV) lithography, and/or extreme ultraviolet (EUV) lithography (using, for example, exposing light having a wavelength of 193 nm, 157 nm, 126 nm, or 13.4 nm). In this regard, photoresist layer 120 may have a thickness in the range of 15-1000 nm, with a preferred thickness in the range of 50-500 nm.

Chamber 104 of lithographic system 100 can be a vacuum for EUV lithography or a nitrogen filled chamber for use in VUV lithography. Chamber 104 can contain any of numerous types of atmospheres, such as air, nitrogen, etc. Alternatively, lithographic system 100 can be utilized in various other types of lithography including lithography that uses electromagnetic radiation at any number of wavelengths, or electron and/or ion beams.

Radiation source 106 provides light or electromagnetic radiation through condenser lens assembly 108, mask or reticle 110, and objective lens assembly 112 to photoresist layer 120. In one embodiment, radiation source 106 may be an excimer laser that produces light having a wavelength of 248 nm, 193 nm, 172 nm, 157 nm, or 126 nm, or a soft x-ray source that produces light having a wavelength of 13.4 nm. Alternatively, radiation source 106 may be any suitably configured light source capable of emitting radiation having a wavelength in the ultraviolet (UV), VUV, DUV, EUV, or x-ray range. Alternatively, the system may utilize a suitably configured electron/ion beam source.

Assemblies 108 and 112 include lenses, mirrors, collimators, beam splitters, and/or other optical components to suitably focus and direct a pattern of radiation (i.e., radiation from radiation source 106 as modified by a pattern or image provided on mask or reticle 110) onto photoresist layer 120. Stage 114 supports wafer 102 and can move wafer 102 relative to assembly 112.

Mask or reticle 110 is a binary mask in one embodiment. Mask or reticle 110 includes a transparent or translucent substrate 122 (e.g., glass or quartz) and an opaque or patterned layer 124 (which may be formed from chromium or chromium oxide) thereon. Opaque layer 124 provides a pattern or image associated with a desired circuit pattern, features, or devices to be projected onto photoresist layer 120. Alternatively, mask or reticle 110 may be an attenuating phase shift mask, an alternating phase shift mask, or other type of mask or reticle.

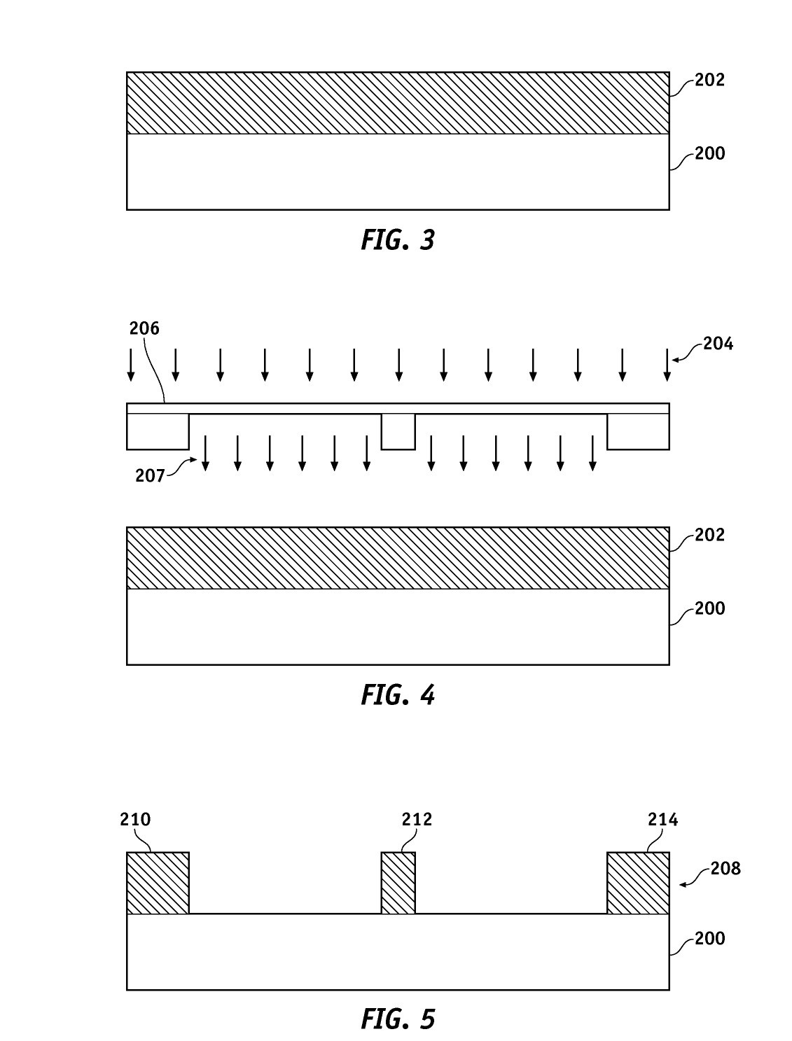

FIGS. 3-12 are cross sectional views of a semiconductor wafer undergoing a double exposure fabrication process. The double exposure fabrication process may be utilized to fabricate an IC having close tolerances between circuit features and/or very narrow line widths. Portions of the double exposure fabrication process may be performed by a lithographic system such as lithographic system 100. In practice, a double exposure fabrication process may include any number of additional or alternative tasks, and the depicted double exposure process may be incorporated into a more comprehensive manufacturing process having additional process steps that are not described in detail herein. Moreover, well known and conventional fabrication steps and techniques will not be described in detail herein.

FIG. 3 depicts a target material of the wafer, which in this example is a semiconductor substrate 200. After appropriate treatment and preparation of semiconductor substrate 200, a suitable photoresist material is deposited over semiconductor substrate 200, forming a photoresist layer 202. As mentioned above, photoresist layer 202 may be formed by spin coating the photoresist material onto semiconductor substrate 200. Photoresist layer 202 may be subjected to a pre-exposure baking step to prepare it for exposure.

FIG. 4 depicts patterning of photoresist layer 202, which is accomplished by exposing photoresist layer 202 to radiation 204 having a wavelength that is appropriate for the particular photoresist material. For example, certain embodiments may utilize DUV radiation having a wavelength of 248 nm or 193 nm. As described above in the context of lithographic system 100, this radiation 204 passes through various optical elements and a mask or reticle 206 that contains a desired pattern. Thus, the pattern or image provided on mask or reticle 206 is transferred to photoresist layer 202 using patterned radiation 207, and photoresist layer 202 chemically reacts to the radiation 207. In practice, the photoresist material in photoresist layer 202 is sufficiently transparent to the radiation 204 to allow useful patterning of the photoresist layer.

Next, the wafer, including the exposed photoresist layer 202, undergoes development to form a patterned photoresist layer. FIG. 5 depicts the resulting patterned photoresist layer 208. The developing step eliminates some of the photoresist material to define a first pattern of photoresist features (such as a feature 210, a feature 212, and a feature 214) in patterned photoresist layer 208. A given feature can define, but is not limited to, a conducting line, a transistor gate, a contact hole, a via, or a trench. In practice, these features may have a relatively high aspect ratio, i.e., the height of a given feature may be greater than or equal to the width of the feature. It should be appreciated that the size and shape of these features are not shown in a limiting fashion.

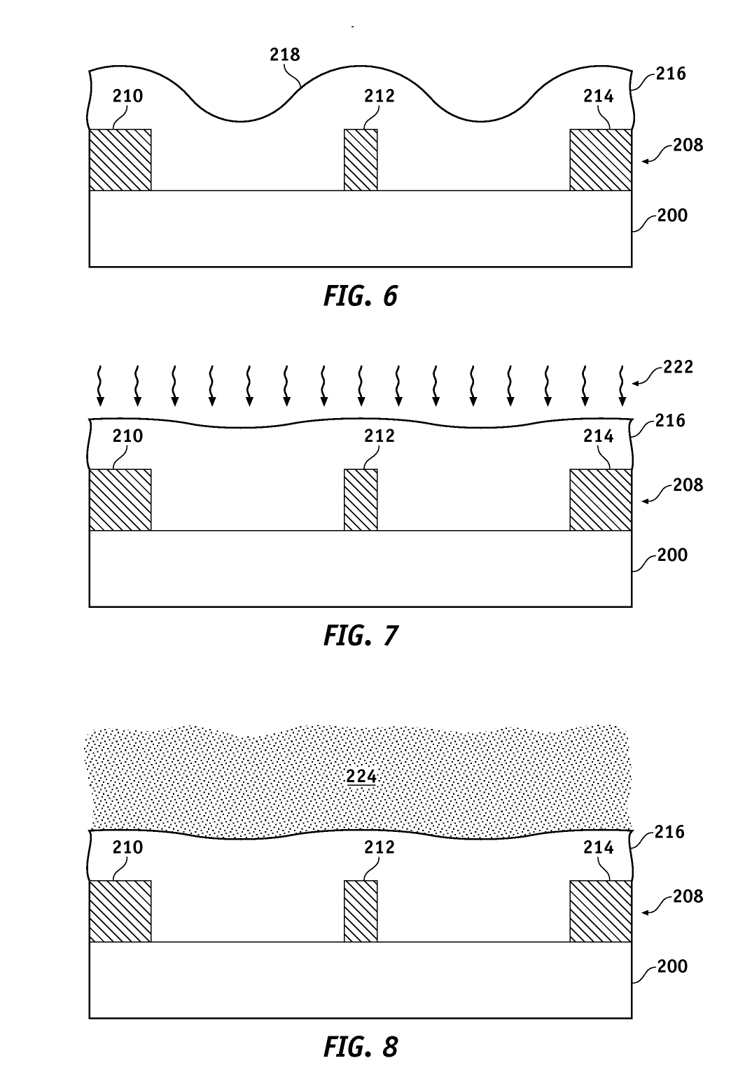

In one embodiment, FIG. 5 represents the result of the first lithographic sub-process in a double exposure device fabrication process. In other words, FIG. 5 depicts the creation of a first pattern of photoresist features over a target material of the semiconductor wafer. In many instances, a stabilizing process such as ion-bombardment, electron-bombardment, ultraviolet exposure, or chemical coating can be used to stabilize the first photoresist pattern prior to coating the second photoresist layer. For embodiments described here, the phrase “creating a first pattern of photoresist features” is intended to include such optional stabilization methods. In accordance with the double exposure process, after the patterned photoresist layer 208 has been developed but before its pattern is transferred onto any of the underlying layers, the patterned photoresist layer 208 may be covered with a second photoresist layer. FIG. 6 depicts a process step of forming (or applying) a second photoresist layer 216 over the target material (semiconductor substrate 200) and over the patterned photoresist layer 208. In some embodiments, the second photoresist material is the same as the first photoresist material. In other embodiments, the second photoresist material is different than the first photoresist material. Different photoresist materials may be desirable to ensure that subsequent treatment of second photoresist layer 216 does not alter or modify patterned photoresist layer 208.

In practice, second photoresist layer 216 may have a non-planar exposed surface 218 that is influenced by patterned photoresist layer 208. As shown in an exaggerated manner in FIG. 6, features 210, 212, and 214 cause the second photoresist material to become contoured with peaks and valleys that roughly correspond to the locations of features 210, 212, and 214. Such non-planar characteristics are exacerbated when features 210, 212, and 214 have relatively high aspect ratios. These surface irregularities are undesirable for the reasons mentioned above with reference to FIG. 1.

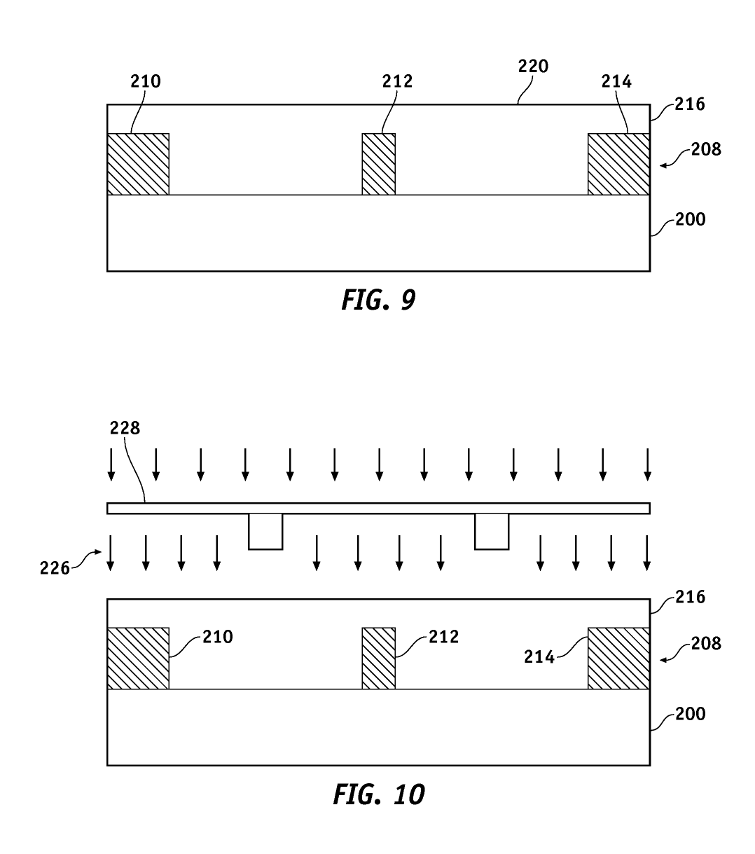

Using the techniques and technologies described here, the contours and irregularities in non-planar exposed surface 218 are reduced by reflowing second photoresist layer 216 to relax non-planar exposed surface 218. Relaxation of non-planar exposed surface 218 preferably results in a substantially planarized exposed surface 220 of second photoresist layer 216 (see FIG. 9).

In one embodiment (depicted in FIG. 7), reflowing second photoresist layer 216 is accomplished by heating second photoresist layer 216 at a designated bake temperature that softens second photoresist layer 216. In such an embodiment, the second photoresist material may be, without limitation, any of the materials described above for photoresist layer 120. In practice, second photoresist layer 216 is heated for a designated period of time. In one non-limiting example, second photoresist layer 216 is heated to a temperature within the range of about 50 to 200° C. for a time period within the range of about 10 to 600 seconds. The particular temperature and baking time may vary depending upon the composition of the second photoresist material, the severity of the non-planar irregularities in the exposed surface of the second photoresist material, the size of the wafer, etc. Notably, the bake temperature and the heating time period are selected such that second photoresist layer 216 is softened without altering patterned photoresist layer 208. In other words, features 210, 212, and 214 are preserved during the heating of second photoresist layer 216. The wavy arrows 222 in FIG. 7 represent the application of heat to second photoresist layer 216, and FIG. 7 depicts a state of reflow where the second photoresist material has softened and the contoured exposed surface of the second photoresist material has started to relax and settle into a planarized condition. In this regard, the exposed surface of the second photoresist material is less contoured than non-planar exposed surface 218 (see FIG. 6), but may not be totally planar.

In another embodiment (depicted in FIG. 8), reflowing second photoresist layer 216 is accomplished by exposing second photoresist layer 216 to a solvent 224 that softens second photoresist layer 216. In such an embodiment, the second photoresist material may be, without limitation, any of the materials described above for photoresist layer 120. In practice, second photoresist layer 216 is exposed to solvent 224 for a designated period of time. The particular solvent used and the solvent exposure time may vary depending upon the composition of the second photoresist material, the severity of the non-planar irregularities in the exposed surface of the second photoresist material, the size of the wafer, etc. Notably, the characteristics and composition of solvent 224, and the time period during which second photoresist layer 216 is exposed to solvent 224, are selected such that second photoresist layer 216 is softened without altering patterned photoresist layer 208. In other words, features 210, 212, and 214 are preserved during exposure of second photoresist layer 216 to solvent 224.

Solvent 224 may be realized using a solvent vapor, a solvent liquid, or a combination thereof. For example, solvent 224 may be introduced in vapor form such that it disperses evenly across the exposed surface of second photoresist layer 216. FIG. 8 depicts a state of reflow where the second photoresist material has softened and the contoured exposed surface of the second photoresist material has started to relax and settle into a planarized condition. In this regard, the exposed surface of the second photoresist material is less contoured than non-planar exposed surface 218 (see FIG. 6), but may not be completely planar. In one non-limiting example, second photoresist layer 216 is exposed to solvent 224 for a time period within the range of 10 to 600 seconds. In practice, solvent 224 may be, without limitation, a carbon-based alcohol, carbonate, ester, ether, hydrocarbon, ketone, or other carbon-based compound containing any of the following additional elements: hydrogen, oxygen, fluorine, chlorine, bromine, or sulfur. The solvent may also contain compositional and isomeric mixtures of any of these compounds.

FIG. 9 depicts a state after formation of planarized exposed surface 220 (using either the bake-based reflow technique or the solvent-based reflow technique. In practice, the “planarized” or “planar” surface need not be perfectly flat, and a substantially planar exposed surface 220 may be acceptable for purposes of creating accurate and precise photoresist features as described herein. In this regard, a “planarized” or “planar” exposed surface 220 will be flat enough to enable the lithographic tool to properly focus on the second photoresist layer 216 such that lensing and other undesirable optical effects are reduced or eliminated.

For the bake-based reflow technique, after planarized exposed surface 220 has been obtained, the baking heat is removed and/or the second photoresist material is cooled to stabilize the second photoresist material. Thus, upon completion of the bake-based reflow step, second photoresist layer 216 includes planarized exposed surface 220 that is free from surface contours and surface irregularities. For the solvent-based reflow technique, after planarized exposed surface 220 has been obtained, the solvent is removed to stabilize the second photoresist material. Thus, upon completion of the solvent-based reflow step, second photoresist layer 216 includes planarized exposed surface 220 that is free from surface contours and surface irregularities.

A further embodiment may perform both the bake-based reflow and the solvent-based reflow, separately or concurrently. For example, it may be desirable to bake second photoresist layer 216 while applying solvent to the exposed surface of second photoresist layer 216. As another example, it may be desirable to perform the bake-based reflow, followed by the solvent-based reflow. Alternatively, the solvent-based reflow can be followed by the bake-based reflow.

The method continues with a second lithographic sub-process associated with a double exposure process. In this regard, FIG. 10 depicts the patterning of second photoresist layer 216; this second patterning step may be similar to the first patterning step described above with reference to FIG. 4. Thus, patterned radiation 226 having an appropriate wavelength is exposed to second photoresist layer 216 using a second mask or reticle 228 that contains a desired pattern. In this example, second mask or reticle 228 defines a pattern that cooperates with the first patterned photoresist layer 208. Thus, the pattern or image provided on mask or reticle 228 is transferred to second photoresist layer 216, which chemically reacts to the radiation 226.

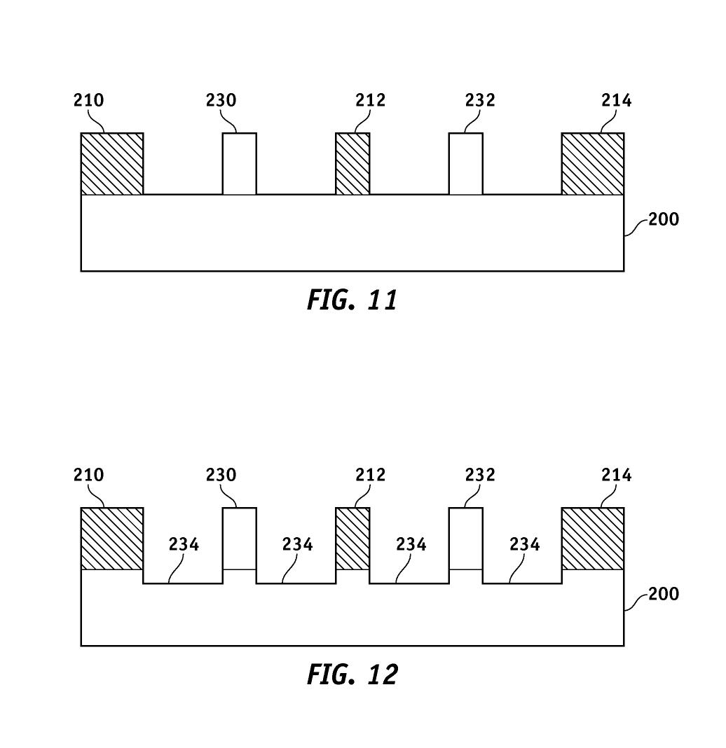

Next, the wafer, including the exposed second photoresist layer 216, undergoes development to form a double patterned photoresist layer. FIG. 11 depicts the resulting double patterned photoresist layer. The double patterned photoresist layer represents an overall photoresist pattern for the semiconductor wafer; this overall photoresist pattern is formed by the first pattern of photoresist features (reference numbers 210, 212, and 214) combined with the second pattern of photoresist features (reference numbers 230 and 232). This second developing step eliminates some of the second photoresist layer 216 to define features 230 and 232 in the double patterned photoresist layer, where a given feature may define or represent any of the elements described above in connection with FIG. 5. Notably, features 230 and 232 represent accurate, undistorted, “high fidelity” features that retain their intended shapes due to the planar exposed surface of second photoresist layer 216 (the planar exposed surface enhances the optical characteristics of second photoresist layer 216, and reduces unwanted reflections and refractions of patterned radiation 226). If desired, the developed photoresist features may be subjected to a final baking step to further define their dimensions. Although not depicted in the figures, the wafer may undergo more than two lithographic sub-processes in this manner.

In accordance with one embodiment, the double patterned photoresist layer is utilized during an etching step where an area of the target material (e.g., semiconductor substrate 200) is etched away. FIG. 12 depicts the result of such an etching step, where areas of the target material that are unprotected or uncovered by the double patterned photoresist layer are etched, forming etched areas 234 in the target material. Although not depicted in the figures, the double patterned photoresist layer can be removed after the etching step to facilitate further processing of the wafer as needed.

In accordance with another embodiment, the double patterned photoresist layer is utilized during an ion implantation step where an area of the target material (e.g., semiconductor substrate 200) is implanted with ions. Here, areas of the target material that are unprotected or uncovered by the double patterned photoresist layer are implanted with ions, forming doped regions in the target material. Although not depicted in the figures, the double patterned photoresist layer can be removed after the ion implantation step to facilitate further processing of the wafer as needed.

While at least one example embodiment has been presented in the foregoing detailed description, it should be appreciated that a vast number of variations exist. It should also be appreciated that the example embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method of creating photoresist features on a semiconductor wafer, the method comprising:
creating a first pattern of photoresist features over a target material of the semiconductor wafer;
forming a second photoresist layer over the target material and over the first pattern of photoresist features, the second photoresist layer having a non-planar exposed surface that is influenced by the first pattern of photoresist features; and
reflowing the second photoresist layer to relax the non-planar exposed surface, resulting in a substantially planarized exposed surface of the second photoresist layer.

2. A method according to claim 1, further comprising:
exposing the second photoresist layer with patterned radiation, resulting in an exposed second photoresist layer; and
developing the exposed second photoresist layer into a second pattern of photoresist features; wherein
the second pattern of photoresist features and the first pattern of photoresist features form an overall photoresist pattern for the semiconductor wafer.

3. A method according to claim 1, wherein reflowing the second photoresist layer comprises heating the second photoresist layer at a bake temperature that softens the second photoresist layer without altering the first pattern of photoresist features.

4. A method according to claim 3, further comprising cooling the second photoresist layer after formation of the substantially planarized exposed surface of the second photoresist layer.

5. A method according to claim 1, wherein reflowing the second photoresist layer comprises exposing the second photoresist layer to a solvent vapor that softens the second photoresist layer without altering the first pattern of photoresist features.

6. A method according to claim 5, wherein reflowing the second photoresist layer further comprises heating the second photoresist layer at a bake temperature that softens the second photoresist layer without altering the first pattern of photoresist features.

7. A method according to claim 5, further comprising removing the solvent vapor after formation of the substantially planarized exposed surface of the second photoresist layer.

8. A method according to claim 1, wherein reflowing the second photoresist layer comprises exposing the second photoresist layer to a solvent liquid that softens the second photoresist layer without altering the first pattern of photoresist features.

9. A method of processing a semiconductor wafer, the method comprising:
creating, from a first photoresist material, a first pattern of photoresist features over a target material of the semiconductor wafer;
applying a second photoresist material over the target material and over the first pattern of photoresist features;
heating the second photoresist material at a bake temperature to soften the second photoresist material while preserving the first pattern of photoresist material, resulting in a substantially planarized exposed surface of the second photoresist material;
exposing the second photoresist material with patterned radiation, resulting in an exposed second photoresist layer; and
developing the exposed second photoresist layer into a second pattern of photoresist features, where the first pattern of photoresist features and the second pattern of photoresist features form an overall photoresist pattern for the semiconductor wafer.

10. A method according to claim 9, wherein heating the second photoresist material causes the second photoresist material to reflow.

11. A method according to claim 9, further comprising cooling the second photoresist material after formation of the substantially planarized exposed surface of the second photoresist material.

12. A method according to claim 9, further comprising etching an area of the target material that is unprotected by the overall photoresist pattern.

13. A method according to claim 9, further comprising exposing the second photoresist material to a solvent to soften the second photoresist material while preserving the first pattern of photoresist material.

14. A method of processing a semiconductor wafer, the method comprising:
creating, from a first photoresist material, a first pattern of photoresist features over a target material of the semiconductor wafer;
applying a second photoresist material over the target material and over the first pattern of photoresist features;
exposing the second photoresist material to a solvent to soften the second photoresist material while preserving the first pattern of photoresist material, resulting in a substantially planarized exposed surface of the second photoresist material;
exposing the second photoresist material with patterned radiation, resulting in an exposed second photoresist layer; and
developing the exposed second photoresist layer into a second pattern of photoresist features, where the first pattern of photoresist features and the second pattern of photoresist features form an overall photoresist pattern for the semiconductor wafer.

15. A method according to claim 14, wherein exposing the second photoresist material to the solvent causes the second photoresist material to reflow.

16. A method according to claim 14, further comprising etching an area of the target material that is unprotected by the overall photoresist pattern.

17. A method according to claim 14, further comprising removing the solvent after formation of the substantially planarized exposed surface of the second photoresist material.

18. A method according to claim 14, further comprising heating the second photoresist material at a bake temperature to soften the second photoresist material while preserving the first pattern of photoresist material.

19. A method according to claim 14, wherein exposing the second photoresist material to a solvent comprises exposing the second photoresist material to a carbon-based compound selected from the group consisting of: alcohol, carbonate, ester, ether, hydrocarbon, or ketone.
